(19) United States
(12) Patent Application Publication
(10) Pub. No.: US 2026/0198253 A1
(43) Pub. Date: Jul. 9, 2026

(54) MICROWAVE ANNEALING FOR LOW-TEMPERATURE HIGH-POWER APPLICATIONS

(71) Applicant: Applied Materials, Inc., Santa Clara, CA (US)

(72) Inventors: Wolfgang Robert Aderhold, Santa Clara, CA (US); Shi You, San Jose, CA (US); Shashank Sharma, Fremont, CA (US)

(21) Appl. No.: 19/012,725

(22) Filed: Jan. 7, 2025

(51) Int. Cl. H01L 21/67; H01L 21/324

(52) U.S. Cl. CPC H10P 72/0436; H10P 95/90

(57) ABSTRACT

A system includes a support base comprising a conductive material, where the support base is to support an activation region. The system further includes a microwave annealing chamber, configured to perform a microwave annealing operation on the activation region supported by the support base to activate the activation region. The support base is disposed within a processing volume of the microwave annealing chamber.

### TECHNICAL FIELD

The present disclosure generally relates to systems and methods for manufacturing a semiconductor device. More particularly, the present disclosure generally relates to a system and a method for thermally processing a substrate.

### BACKGROUND

Substrate processing can utilize operations that output large amounts of heat that can damage semiconductor devices during manufacture. By limiting heating of substrates during microwave annealing processes in processing chambers (e.g., microwave annealing processing chambers), damage due to heat can be mitigated.

### SUMMARY

The following is a simplified summary of the disclosure in order to provide a basic understanding of some aspects of the disclosure. This summary is not an extensive overview of the disclosure. It is intended to neither identify key or critical elements of the disclosure, nor delineate any scope of the particular implementations of the disclosure or any scope of the claims. Its sole purpose is to present some concepts of the disclosure in a simplified form as a prelude to the more detailed description that is presented later.

In one aspect of the disclosure, a system for implementing methods such as those discussed below is disclosed. The system includes a support base including a conductive material. The support base is to support an activation region. The system further includes a microwave annealing chamber, configured to perform a microwave annealing operation on the activation region supported by the support base to activate the activation region. The support base is disposed within a processing volume of the microwave annealing chamber.

In another aspect of the disclosure, a method includes coupling an activation region to a support base, wherein the support base includes a conductive material. The method further includes causing the activation region coupled to the support base to undergo a microwave annealing operation in a processing chamber to activate the activation region.

In another aspect of the disclosure, a substrate carrier for implementing methods such as those discussed below is disclosed. The substrate carrier is disposed within a processing volume of a microwave annealing chamber. The substrate carrier is to support a substrate including an activation region. The substrate carrier includes a conductive material. The microwave annealing chamber is configured to perform a microwave annealing operation on the substrate to activate the activation region of the substrate.

### BRIEF DESCRIPTION OF THE DRAWINGS

The present disclosure is illustrated by way of example, and not by way of limitation in the figures of the accompanying drawings.

FIG. 1 is a top schematic view of an example electronic device manufacturing system, in accordance with some embodiments.

FIG. 2 is a cross-sectional view of a processing chamber (e.g., a semiconductor wafer processing chamber) according to some embodiments.

FIG. 3 is a flow diagram of a method associated with low-temperature high-power microwave annealing, according to certain embodiments.

FIG. 4 is a block diagram illustrating a computer system, according to certain embodiments.

### DETAILED DESCRIPTION

Described herein are technologies directed to low-temperature high-power microwave annealing in a manufacturing process. Manufacturing equipment is used to produce substrates, such as semiconductor wafers. The properties of these substrates are controlled by the conditions under which the substrates are processed.

For example, semiconductor device fabrication can include creation of backside power distribution networks to enhance the power delivery and performance of integrated circuits (ICs). A critical step in this process is the formation of highly conductive contacts, typically achieved through solid-phase epitaxy. This technique involves implanting dopant atoms into a substrate to amorphize a layer, which is later recrystallized to form a conductive layer. The recrystallization is facilitated by annealing—a heat treatment that restores the crystal structure, thereby enhancing the electrical properties of the doped regions. In other processes, an activation region is to be activated using annealing operations to improve its electrical properties and performance.

Maintaining low processing temperatures during annealing preserves substrate integrity and overall device performance. However, conventional thermal annealing methods often anneal at temperatures above 400 degrees Celsius to effectively activate target regions (e.g., recrystallize doped regions). Annealing at temperatures above 400 degrees is particularly prevalent in doped regions having N-type dopants. Such high-temperature processing poses risks to the substrate, potentially leading to degradation and suboptimal device performance.

Moreover, annealing at temperatures at or below 400 degrees Celsius can be highly time-consuming and may not always fully activate the target regions (activation regions). For example, prolonged durations are necessary to achieve target activation, which can cause inefficiencies in the manufacturing process and result in inconsistent product quality. This challenge can be especially pronounced with N-type dopants, where low-temperature annealing often fails to sufficiently recrystallize the amorphized layer, leading to poor electrical performance.

Microwave annealing has emerged as a potential solution to achieve low-temperature activation (e.g., recrystallization). However, this method can result in exceeding the thermal budget and often heats the entire substrate—not just the targeted activation regions. This broad heating effect can make it challenging to maintain an even substrate temperature below 400 degrees Celsius, negatively impacting device integrity and thwarting precise thermal management. Consequently, microwave annealing methods struggle to effectively activate a target region while maintaining a strict thermal budget, especially due to residual heating effects.

Aspects and implementations of the present disclosure address these and other shortcomings of the existing technologies by implementing systems and methods for low-temperature, high-power microwave annealing. For example, a system can include a support base made from a conductive material, which supports a region of a substrate that is to be activated (e.g., an activation region). The support base can be, for example, one of a doped substrate, a substrate carrier, a substrate support pedestal, and/or the like. In some embodiments, the support base can be an actual substrate, which is highly doped (e.g., with a resistivity between 0.001 Ohm-cm and 0.1 Ohm-cm) and conductive. The highly doped substrate can have additional low-doped (e.g., with a resistivity between 1 Ohm-cm and 100 Ohm-cm) epitaxial grown layers for device structures (e.g., gates and drains in a transistor) and one or more activation regions to be annealed.

The system can include a microwave annealing chamber to perform a microwave annealing operation on the activation region. During microwave annealing operation, the activation region (disposed within the processing volume of the microwave annealing chamber) can receive microwaves. The microwave annealing chamber can deliver electromagnetic radiation to the activation region. The conductive properties of the support base can cause the electromagnetic radiation to be reflected away from the activation region, allowing the activation region to be activated (e.g., recrystallized) without overheating.

By utilizing conductive materials as a support base, heating an activation region beyond a thermal budget can be avoided during microwave exposure. This can be particularly useful, for example, for backside power rail anneals. By placing the conductive material or substrate close to the region to be annealed (the conductive material can either be integrated into the wafer bulk or can be part of a carrier wafer or substrate carrier), electromagnetic waves can be reflected away from the activation region and absorption of energy by the activation region can be prevented, allowing for lower temperatures during microwave exposure.

Aspects and implementations of the present disclosure enable low processing temperatures during microwave annealing to preserve the integrity of the substrate while activating the target region, leading to enhanced overall performance of the device. Aspects of the present disclosure are time efficient, and eliminate conventional annealing methods that use prolonged durations to achieve target activation, eliminating inefficiencies in the manufacturing process. Aspects and implementations of the present disclosure result in consistent product quality, and allow for the activation of target regions (e.g., activation regions) while maintaining a low thermal budget and ensuring timely processing, leading to enhanced electrical performance.

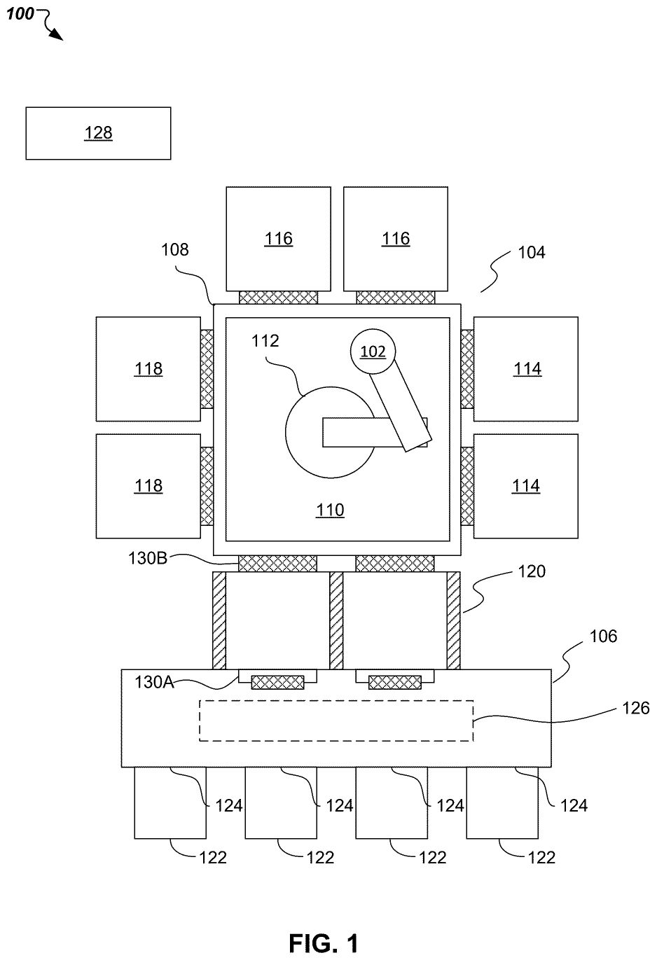

FIG. 1 is a top schematic view of an example electronic device manufacturing system 100, in accordance with some embodiments of the present disclosure. It is noted that FIG. 1 is used for illustrative purposes, and that different components can be positioned in different locations in relation to each view. In some embodiments, system 100 includes multiple processing chambers (e.g., for low-temperature high-power microwave annealing).

Electronic device manufacturing system 100 (also referred to as an electronics processing system) is configured to perform one or more processes on a substrate 102. Substrate 102 can be any suitably rigid, fixed-dimension, planar article, such as, e.g., a silicon-containing disc or wafer, a patterned wafer, a glass plate, or the like, suitable for fabricating electronic devices or circuit components thereon.

Electronic device manufacturing system 100 includes a process tool 104 (e.g., a mainframe) and a factory interface 106 (e.g., an EFEM) coupled to process tool 104. Process tool 104 includes a housing 108 having a transfer chamber 110 therein. Transfer chamber 110 includes one or more processing chambers (also referred to as process chambers) 114, 116, 118 disposed therearound and coupled thereto. Processing chambers 114, 116, 118 can be coupled to transfer chamber 110 through respective ports, such as slit valves or the like.

Processing chambers 114, 116, 118 can be adapted to carry out any number of processes on substrates 102. A same or different substrate process can take place in each processing chamber 114, 116, 118. Examples of substrate processes include annealing (e.g., microwave annealing for low thermal budget applications), atomic layer deposition (ALD), physical vapor deposition (PVD), chemical vapor deposition (CVD), etching, curing, pre-cleaning, metal or metal oxide removal, or the like. In one example, a PVD process is performed in one or both of process chambers 114, an etching process is performed in one or both of process chambers 116, and a microwave annealing process is performed in one or both of process chambers 118. Other processes can be carried out on substrates therein. Processing chambers 114, 116, 118 can each include a substrate support assembly. The substrate support assembly can be configured to hold a substrate in place while a substrate process is performed.

In some embodiments, processing chambers 118 can include a support base made from a conductive material, which supports an activation region of substrate 102 that is to be activated. In some embodiments, the support base can be a substrate carrier or a substrate support pedestal.

Processing chambers 118 can be microwave annealing chambers for performing microwave annealing operations on the activation region of substrate 102. During a microwave annealing operation, the activation region can receive microwaves generated by processing chambers 118. The microwave annealing chambers 118 can deliver electromagnetic radiation to the activation region that is reflected away from the activation region by the conductive support base allowing the activation region to be activated (e.g., recrystallized) without overheating. In some embodiments, a temperature of substrate 102 and/or the activation region does not exceed 400 degrees Celsius during the microwave annealing process.

Transfer chamber 110 can also include a transfer chamber robot 112. Transfer chamber robot 112 can include one or multiple arms where each arm includes one or more end effectors at the end of each arm. The end effector can be configured to handle particular objects, such as wafers. Alternatively, or additionally, the end effector can be configured to handle objects such as process kit rings. In some embodiments, transfer chamber robot 112 is a selective compliance assembly robot arm (SCARA) robot, such as a 2-link SCARA robot, a 3-link SCARA robot, a 4-link SCARA robot, and so on.

A load lock 120 can also be coupled to housing 108 and transfer chamber 110. Load lock 120 can be configured to interface with, and be coupled to, transfer chamber 110 on one side and factory interface 106 on another side. Load lock 120 can have an environmentally-controlled atmosphere that is changed from a vacuum environment (where substrates are transferred to and from transfer chamber 110) to an at or near atmospheric-pressure inert-gas environment (where substrates are transferred to and from factory interface 106). In some embodiments, load lock 120 is a stacked load lock having a pair of upper interior chambers and a pair of lower interior chambers that are located at different vertical levels (e.g., one above another). In some embodiments, the pair of upper interior chambers are configured to receive processed substrates from transfer chamber 110 for removal from process tool 104, while the pair of lower interior chambers are configured to receive substrates from factory interface 106 for processing in process tool 104. In some embodiments, load lock 120 is configured to perform a substrate process (e.g., an etch or a pre-clean) on one or more substrates 102 received therein.

Factory interface 106 can be any suitable enclosure, such as, e.g., an Equipment Front End Module (EFEM). Factory interface 106 can be configured to receive substrates 102 from substrate carriers 122 (e.g., Front Opening Unified Pods (FOUPs)) docked at various load ports 124 of factory interface 106. A factory interface robot 126 (shown dotted) can be configured to transfer substrates 102 between substrate carriers 122 (also referred to as containers) and load lock 120. In other and/or similar embodiments, factory interface 106 is configured to receive replacement parts from replacement parts storage containers. Factory interface robot 126 can include one or more robot arms and can be or include a SCARA robot. In some embodiments, factory interface robot 126 has more links and/or more degrees of freedom than transfer chamber robot 112. Factory interface robot 126 can include an end effector on an end of each robot arm. The end effector can be configured to pick up and handle specific objects, such as wafers. Alternatively, or additionally, the end effector can be configured to handle objects such as process kit rings. Any conventional robot type can be used for factory interface robot 126. Transfers can be carried out in any order or direction. Factory interface 106 can be maintained in, e.g., a slightly positive-pressure nonreactive gas environment (using, e.g., nitrogen, other inert gasses, or air with controlled sub-component parameters as the nonreactive gas) in some embodiments.

Factory interface 106 can be configured with any number of load ports 124, which can be located at one or more sides of the factory interface 106 and at the same or different elevations.

Factory interface 106 can include one or more auxiliary components (not shown). The auxiliary components can include substrate storage containers, metrology equipment, servers, air conditioning units, etc. A substrate storage container can store substrates and/or substrate carriers (e.g., FOUPs), for example. Metrology equipment can be used to determine property data of the products that were produced by the electronic device manufacturing system 100. In some embodiments, factory interface 106 can include an upper compartment. The upper compartment can house electronic systems (e.g., servers, air conditioning units, etc.), utility cables, system controller 128, or other components. In some embodiments, the electronic systems, utility cables, etc. housed in the upper compartment include a processing chamber for low-temperature high-power microwave annealing applications as described herein.

In some embodiments, transfer chamber 110, process chambers 114, 116, and 118, and/or load lock 120 are maintained at a vacuum level. Electronics processing system 100 can include one or more vacuum ports that are coupled to one or more stations of electronic device manufacturing system 100. For example, first vacuum ports 130A can couple factory interface 106 to load locks 120. Second vacuum ports 130B can be coupled to load locks 120 and disposed between load locks 120 and transfer chamber 110.

Electronic device manufacturing system 100 can also include a system controller 128. System controller 128 can be /r include a computing device such as a personal computer, a server computer, a programmable logic controller (PLC), a microcontroller, and so on. System controller 128 can include one or more processing devices, which can be general-purpose processing devices such as a microprocessor, central processing unit, or the like. More particularly, the processing device can be a complex instruction set computing (CISC) microprocessor, reduced instruction set computing (RISC) microprocessor, very long instruction word (VLIW) microprocessor, or a processor implementing other instruction sets or processors implementing a combination of instruction sets. The processing device can also be one or more special-purpose processing devices such as an application specific integrated circuit (ASIC), a field programmable gate array (FPGA), a digital signal processor (DSP), network processor, or the like. System controller 128 can include a data storage device (e.g., one or more disk drives and/or solid state drives), a main memory, a static memory, a network interface, and/or other components. System controller 128 can execute instructions to perform any one or more of the methodologies and/or embodiments described herein. The instructions can be stored on a computer readable storage medium, which can include the main memory, static memory, secondary storage and/or processing device (during execution of the instructions). System controller 128 can include an environmental controller configured to control an environment (e.g., gas pressure, moisture level, vacuum level, etc.) within factory interface 106. System controller 128 can also be configured to permit entry and display of data, operating commands, and the like by a human operator.

In some embodiments, system controller 128 may be coupled with other components of system 100 (e.g., process chambers 114, 116, and 118, transfer chamber 110, transfer chamber robot 112, etc.) via any suitable connection type. For example, system controller 128 may be coupled with process chamber 118 and subcomponents of process chamber 118 (e.g., an electromagnetic radiation source of process chamber 118, etc.) via a network (e.g., local area network (LAN), wide area network (WAN), etc.), a bus connection (e.g., a shared data bus, a serial bus, etc.), a wireless connection (e.g., via Wi-Fi, Bluetooth, etc.), a direct connection (e.g., wired connection), an optical connection, an RF connection, and/or the like

In some embodiments, system controller 128 may cause transfer chamber robot 112 to couple an activation region to a support base. In some embodiments, the system controller 128 can send instructions to the transfer chamber robot 112 to cause the transfer chamber robot to couple the activation region to the support base. In some embodiments, the system controller 128 can cause the transfer chamber robot 112 to couple the activation region to the support base based on user input, sensor data, pre-programmed schedules, real-time process conditions, etc. In some embodiments, the support base can include a substrate carrier, a substrate support pedestal, and/or the like.

In some embodiments, system controller 128 may cause the activation region coupled to the support base to undergo a microwave annealing operation in a processing chamber (e.g., process chamber 118) to activate the activation region. In some embodiments, the system controller 128 can send instructions to the processing chamber to cause the microwave annealing operation. In some embodiments, the system controller 128 can cause electromagnetic radiation to be delivered to the activation region and the support base. In some embodiments, the system controller 128 can send instructions to the processing chamber to cause the electromagnetic radiation to be delivered to the activation region and the support base. In some embodiments, the system controller 128 can cause the microwave annealing process to be performed and the electromagnetic radiation to be delivered based on user input, sensor data, pre-programmed schedules, real-time process conditions, etc.

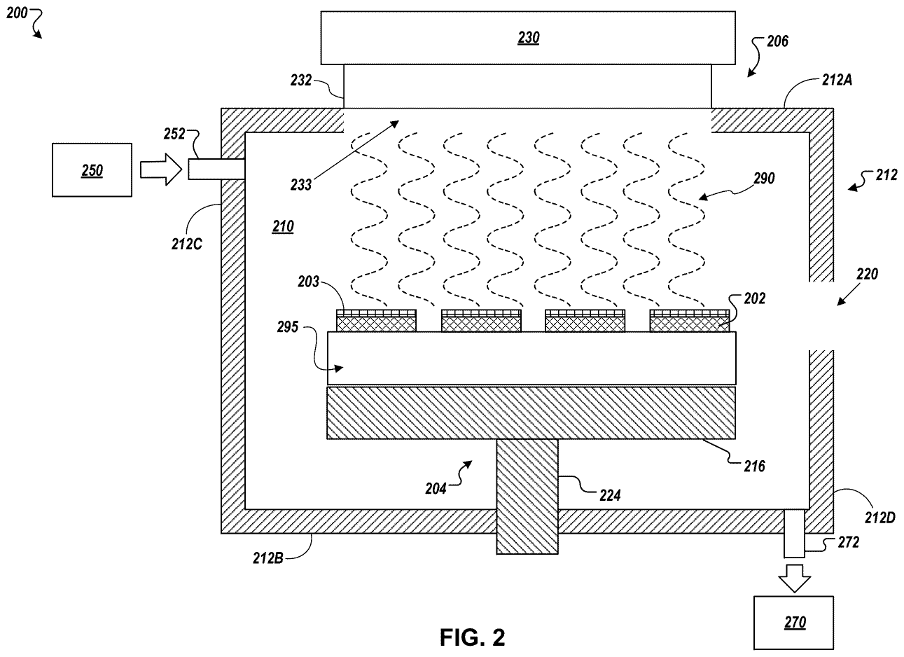

FIG. 2 is a cross-sectional view of a processing chamber (e.g., a semiconductor wafer processing chamber) according to some embodiments. In some embodiments, a processing system 200 includes an electromagnetic energy source 230, which may be a continuous source or pulsed source. In some embodiments, electromagnetic energy source 230 may be a microwave energy source. The processing system 200 may be a semiconductor processing system, for example, a microwave annealing system (e.g., a microwave annealing system for low-temperature high-power microwave annealing). The processing system 200 may be used to perform microwave annealing for low-temperature high-power microwave annealing applications as described herein. The processing system 200 can include a processing chamber 206.

The processing chamber 206 can include a chamber body 212. The chamber body 212 at least partially defines a processing volume 210. In some embodiments, the chamber body 212 includes a top wall 212A (e.g., a ceiling or lid), a bottom wall 212B (e.g., a floor) opposite the top wall 212A, a first sidewall 212C coupling the top wall 212A and the bottom wall 212B, and a second sidewall 212D opposite the first sidewall 212C. The chamber body 212 may be or include any material suitable with the processes performed in the processing chamber 206. For example, suitable materials for the chamber body 212 may include aluminum, stainless steel, ceramic materials, or a combination thereof.

At least one substrate support pedestal 216 is disposed in the processing volume 210 to support one or more substrate(s) 202 thereupon during processing. In some embodiments, a substrate support assembly 204 includes substrate support pedestal 216 and shaft 224. Substrate support assembly 204 supports at least one substrate during processing (e.g., microwave annealing processing for low-temperature high-power microwave annealing applications). The substrate(s) 202 can be brought into the processing volume 210 through a loading port 220. The substrate support pedestal 216 may be any support pedestal for holding one or more semiconductor substrates and may include such components as an electrostatic chuck, clamps, edge rings, guide pins, or the like for physically locating and retaining the substrate. The substrate support pedestal 216 can be made of a conductive material.

The processing system 200 further includes the electromagnetic energy source 230. In some embodiments, the electromagnetic energy source 230 may be, but is not limited to, a microwave energy source, an optical radiation source (e.g., laser or flash lamp), an electron beam source, and/or an ion beam source. For example, the electromagnetic energy source may have a frequency ranging from 0.1 to 300 GHz. In some embodiments, the electromagnetic energy source may have a frequency ranging from 100 kilohertz to 300 gigahertz. The electromagnetic energy source 230 can be continuous or pulsed. In particular embodiments, the electromagnetic energy source 230 is a microwave energy source. The electromagnetic energy source 230 may be coupled with the chamber body 212 via a waveguide 232. The electromagnetic energy generated by the electromagnetic energy source 230 may be supplied into the processing volume 210 from a waveguide launch port 233, which is fluidly coupled with the processing volume 210 via the waveguide 232. Although FIG. 1 shows the waveguide launch port 233 disposed along the top wall 212A of the chamber body 212, the waveguide launch port 233 may also be placed in other locations such as the bottom wall 212B, the first sidewall 212C, the second sidewall 212D, or a combination of different locations.

In some embodiments, the electromagnetic energy source 230 is configured to deliver electromagnetic radiation to the substrates 202.

The electromagnetic energy source 230 may be configured to deliver emitted electromagnetic energy 290 (e.g., electromagnetic radiation) to the activation regions 203 and the support base 295 positioned on the substrate support pedestal 216. The electromagnetic energy source 230 may be a continuous or pulsed source. In some embodiments, the electromagnetic energy source 230 is a continuous source. In some embodiments, the electromagnetic energy source 230 is a microwave energy source (e.g., a continuous microwave energy source). In some embodiments, the emitted electromagnetic energy 290 is emitted microwaves.

In some embodiments, the electromagnetic energy source 230 is a microwave generator. The microwave generator generates a fixed frequency microwave or a variable frequency microwave. The microwave generated in the microwave generator is suppled into the processing volume 210 from the waveguide launch port 233 via the waveguide 232. In one embodiment, the frequency of microwave supplied is in a range from about 1 GHz to about 30 GHz. In another embodiment, the frequency of microwave supplied is in a range from about 1 GHz to about 10 GHz, or in a range from about 2 GHz to about 6 GHz, for example, 2.45 GHz. However, other applicable frequencies may also be used. For example, the electromagnetic energy source may have a frequency ranging from 0.1 to 300 GHz. In some embodiments, the electromagnetic energy source may have a frequency ranging from 100 kilohertz to 300 gigahertz. The power of microwave may be in range from about 100 watts to about 20 kilowatts, or in a range from about 1000 watts to about 3000 watts, or in a range from about one kilowatt to about 50 kilowatts. In one example, the microwave generator outputs 1500 watts of power at a frequency of about 2.54 gigahertz (GHz).

In some embodiments, the substate support pedestal 216 supports a support base 295 that supports substrates 202. Substrates 202 can have at least one activation region 203 (e.g., disposed on the substrate) that can be either directly or indirectly supported (e.g., held) by support base 295. In some embodiments, the support base 295 can be made of a conductive material.

In some embodiments, the conductive material of the support base 295 can be a doped substrate. The doped substrate can include an activation region to be activated by a microwave annealing operation. For example, the support base 295 can be doped silicon, silicon carbide, etc. and can include an activation region. The doped substrate can be conductive and have conductive properties. The conductivity of the doped substrate causes electromagnetic radiation to be reflected away from the activation region. In some embodiments, the doped substrate can be silicon (Si) or silicon carbide (SiC). The doped substrate can have a resistivity ranging from 0.001 to 0.1 Ohms per square (Ω/□) and a thickness between 200 and 1000 micrometers (μm).

In some embodiments, the doped substrate may be highly doped and can include an epitaxial layer, which is low-doped. The highly doped substrate can have a resistivity ranging from 0.001 to 0.1 Ohms/square and a thickness between 200 and 1000 micrometers (μm). The low-doped epitaxial layer can have a higher resistivity that can range from 1 to 100 ohms/cm and a thickness between 2 and 1000 nanometers (nm). The provided ranges are intended solely as illustrative examples, and the described embodiments may be applied to any systems or methods related to a highly doped substrate with an epitaxial layer, irrespective of thickness.

In some embodiments, doped substrate can be a carrier substrate (e.g., with bonded wafers to be annealed or chiplets to be annealed). The carrier substrate can be made from a material similar to that of the bonded wafer (e.g., substrate 202) or chiplets. The bonded wafer or chiplets can be silicon (Si) or silicon carbide (SiC), with a total thickness ranging from 50 to 200 micrometers (μm). The carrier substrate itself can have a resistivity ranging between 0.001 and 0.1 Ohms per square (Ω/□) and a thickness between 200 and 1000 micrometers (μm).

In some embodiments, the activation regions 203 supported by the support base 295 receive microwaves during a microwave annealing operation. In some embodiments, the electromagnetic energy 290 of the microwave annealing operation is delivered by the electromagnetic radiation source 230 to activation region 203 and the support base 295. The support base 295 is configured to reflect the electromagnetic radiation (e.g., electromagnetic energy 290) away from the activation regions 203. In this way, the electromagnetic energy 290 does not heat the substrates 202 and/or activation regions 203 beyond a target thermal budget (e.g., 400 degrees Celsius) and is directed away from activation regions 203, while still allowing the microwave energy of electromagnetic radiation source 230 to activate the activation regions 203.

In some embodiments, support base 295 can be a substrate carrier made of a conductive material. The conductive material can be, for example, copper, aluminum, gold, silver, brass, titanium nitride, tungsten, polyaniline, polypyrrole, graphene, yttrium barium copper oxide, niobium-titanium, etc. The substrate carrier is to support (hold) a substrate having an activation region. The substrate is to reflect electromagnetic radiation away from the activation region during a microwave annealing operation.

In some embodiments, the substrate carrier can be made from a material different from a substrate (wafer) to be annealed. The substrate carrier can be temporarily attached to the wafer using methods such as glue, wax, or vacuum chucking. Alternatively, the substrate carrier does not directly contact the wafer (e.g., there is a gap of 10 micrometers between the substrate carrier and the substrate). The wafer itself can be silicon (Si) or silicon carbide (SiC) and can have a total thickness ranging from 100 to 1000 micrometers (μm). The substrate carrier can have a resistivity of less than 0.1 Ohms per square (Ω/□) and a thickness greater than 1000 micrometers (μm).

In some embodiments, support base 295 can alternatively be substrate support pedestal 216, being disposed within the processing volume 210 and being operable to support the activation regions 203. Substrate support pedestal can be made of a conductive material to reflect electromagnetic radiation away from the activation regions 203 during a microwave annealing operation.

In some embodiments, support base 295 can be a substrate carrier. The substrate carrier is disposed within processing volume 210 of a microwave annealing chamber (e.g., processing chamber 206). The substrate carrier (e.g., support base 295) is to support one or more substrates 202 including one or more activation regions 203. The substrate carrier is made of a conductive material. The microwave annealing chamber (e.g., processing chamber 206) is configured to perform a microwave annealing operation on the one or more substrates 202 to activate the one or more activation regions 203 of the one or more substrates 202. In some embodiments, the substrate carrier is a substrate support pedestal (e.g., substrate support pedestal 216). In some embodiments, the microwave annealing chamber (e.g., processing chamber 206) is configured to deliver electromagnetic radiation (e.g., electromagnetic energy 290) to the one or more substrates 202 and the substrate carrier. The substrate carrier is configured to reflect the electromagnetic radiation away from the one or more substrates 202. In some embodiments, a temperature of the one or more substrates does not exceed 400 degrees Celsius during the microwave annealing operation.

In some embodiments, the processing system 200 further includes a gas supply 250. Gas supply 250 may be fluidly coupled with the processing volume via a gas inlet 252. Gas supply 250 may be coupled to the processing chamber body 212 at any suitable location for supplying gas to the processing volume 210, such as along first sidewall 212C of the chamber body 212, as illustrated. For example, depending upon chamber design and process gas flow considerations, gas inlet 252 may be located at any suitable location in the processing chamber 206, such as in the first sidewall 212C, second sidewall 212D of the processing chamber 206, above or below the surface of the substrate support pedestal 216, in the top wall 212A of the processing chamber 206, in the bottom wall 212B of the processing chamber 206, or in any other suitable location. In some embodiments, gas supply 250 may include one or more pumps and valves utilized to regulate the pressure of processing volume 210 of processing chamber 206.

In some embodiments, the processing system 200 further includes the exhaust system 270. In one implementation, the exhaust system 270 is coupled to the processing chamber body 212 via an exhaust port 272. The exhaust system 270 may be coupled to the processing chamber body 212 at any suitable location for exhausting the processing volume 210, such as along the bottom wall 212B of the chamber body 212, as illustrated. For example, depending upon chamber design and process gas flow considerations, the exhaust port 272 may be located at any suitable location in the processing chamber 206, such as in the first sidewall 112C, second sidewall 112D of the processing chamber 206, above or below the surface of the substrate support pedestal 216, in the top wall 212A of the processing chamber 206, in the bottom wall 212B of the processing chamber 206, or in any other suitable location. In some embodiments, exhaust system 270 may include one or more pumps and valves utilized to evacuate and regulate the pressure of processing volume 210 of processing chamber 206.

Examples of processing gases that may be used in processing system 200 include halogen-containing gases, such as C₂F₆, SF₆, SiCl₄, HBr, NF₃, CF₄, CHF₃, F₂, Cl₂, CCl₄, BCl₃, and SiF₄, among others, and other gases such as O₂ or N₂O. Examples of carrier gases include N₂, He, Ar, and other gases inert to process gases (e.g., non-reactive gases).

The gas supply 250 can provide one or more suitable process gases for processing the substrate(s) 202 and/or for maintaining the processing volume 210 (such as annealing gases, cleaning gases, or the like). For example, aspects of the present disclosure may be used in annealing processes that require certain gases to be provided to the processing volume 210. The gases may be reactive or nonreactive, such as inert gases commonly used in conventional thermal processes. The processing volume 210 within which the substrate(s) 202 resides during processing may be evacuated or contain a gas suitable for the targeted process. In one implementation, the gas supply 250 comprises a plurality of gas sources supplying one or more process gases to the processing volume 210. Each process gas may be supplied independently, or in combination with additional process gases. Other components for controlling the flow of gases to the processing volume 210, such as flow controllers, valves, or the like, are not shown for simplicity.

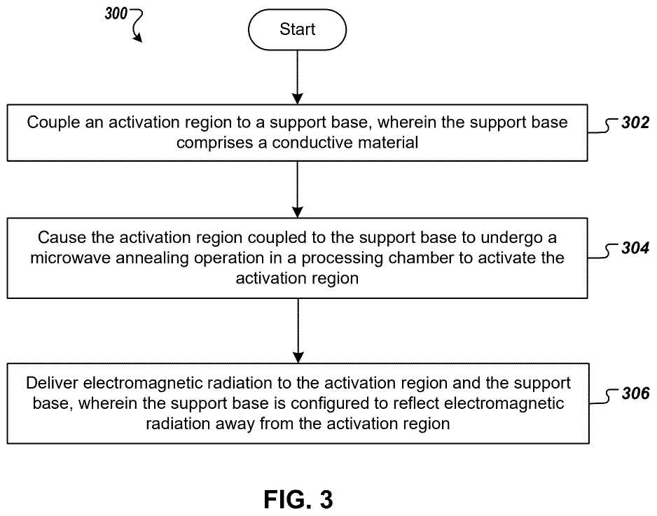

FIG. 3 is a flow diagram of a method 300 associated with low-temperature high-power microwave annealing, according to certain embodiments. Method 300 may be performed by processing logic that may include hardware (e.g., circuitry, dedicated logic, programmable logic, microcode, processing device, etc.), software (such as instructions run on a processing device, a general purpose computer system, or a dedicated machine), firmware, microcode, or a combination thereof. In some embodiment, method 300 may be performed, in part, by processing system 200. In some embodiments, a non-transitory storage medium stores instructions that when executed by a processing device (e.g., of processing system 200) cause the processing device to perform method 300.

For simplicity of explanation, method 300 is depicted and described as a series of operations. However, operations in accordance with this disclosure can occur in various orders and/or concurrently and with other operations not presented and described herein. Furthermore, not all illustrated operations may be performed to implement method 300 in accordance with the disclosed subject matter. In addition, those skilled in the art will understand and appreciate that method 300 could alternatively be represented as a series of interrelated states via a state diagram or events.

Referring to FIG. 3, in some embodiments, at block 302 the processing logic implementing method 300 causes an activation region to be coupled to a support base. The support base comprises a conductive material.

In some embodiments, the processing logic causes a transfer chamber robot to couple the activation region to the support base. The transfer chamber robot can for example position and attach the activation region onto the support base using vacuum suction, adhesive, electrostatic chucking, etc. In some embodiments, the support base can be a substrate carrier and the transfer chamber robot may load the activation region onto the carrier, securing it with holding mechanisms designed for transport and processing. In some embodiments, the support base can be a substrate support pedestal and the transfer chamber robot can align and place the activation region onto the pedestal and secure it with electrostatic chucking for subsequent annealing processes. In some embodiments, the processing logic can send instructions to the transfer chamber robot to cause the transfer chamber robot to couple the activation region to the support base. In some embodiments, the transfer chamber robot couples the activation region to the support base based on user input, sensor data, pre-programmed schedules, real-time process conditions, etc. In some embodiments, the support base can include a substrate carrier, a substrate support pedestal, and/or the like.

At block 304, processing logic causes the activation region coupled to the support base to undergo a microwave annealing operation in a processing chamber to activate the activation region. In some embodiments, the processing logic can send instructions to a processing chamber to cause the microwave annealing operation.

At block 306, processing logic causes electromagnetic radiation to be delivered to the activation region and the support base. In some embodiments, the processing logic can send instructions to an electromagnetic radiation source to cause the electromagnetic radiation source to deliver electromagnetic radiation to the activation region and the support base. The activation region supported by the support base receives microwaves during the microwave annealing operation. In some embodiments, the electromagnetic energy source may have a frequency ranging from 100 kilohertz to 300 gigahertz. In some embodiments, a frequency of the microwaves of the microwave annealing operation ranges from two gigahertz to six gigahertz. In some embodiments, the microwaves are high-power microwaves ranging from one kilowatt to 50 kilowatts.

The support base is configured to reflect electromagnetic radiation away from the activation region.

In some embodiments, the processing logic causes the microwave annealing process to be performed and the electromagnetic radiation to be delivered based on user input, sensor data, pre-programmed schedules, real-time process conditions, etc.

In some embodiments, the support base is a doped substrate, and the activation region is disposed on the doped substrate.

In some embodiments, the support base is a substrate carrier.

In some embodiments, the support base is a substrate support pedestal disposed within a processing volume of the processing chamber and operable to support the activation region.

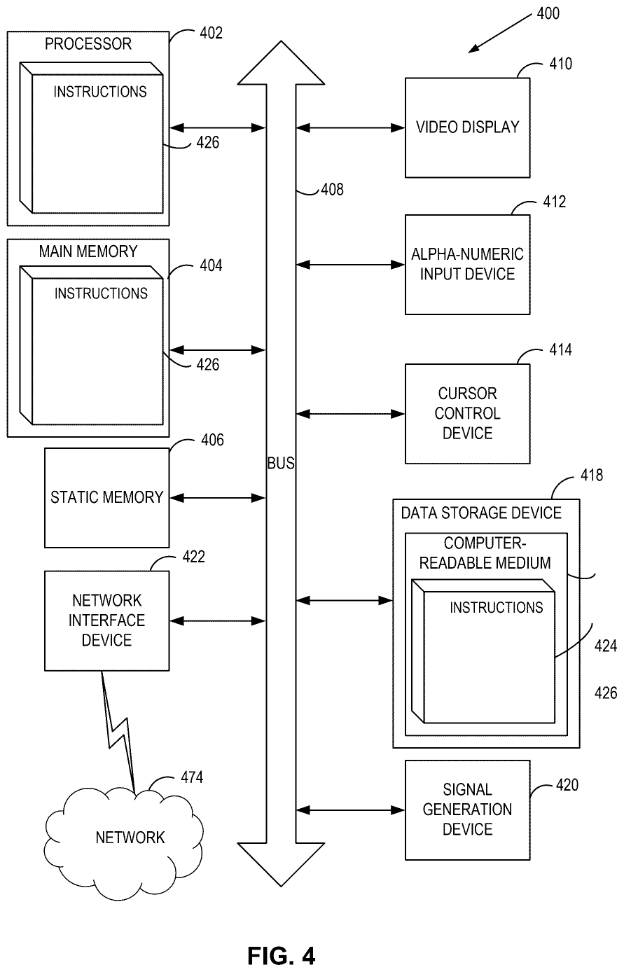

FIG. 4 is a block diagram illustrating a computer system 400, according to certain embodiments. In some embodiments, computer system 400 may be connected (e.g., via a network, such as a Local Area Network (LAN), an intranet, an extranet, or the Internet) to other computer systems. Computer system 400 may operate in the capacity of a server or a client computer in a client-server environment, or as a peer computer in a peer-to-peer or distributed network environment. Computer system 400 may be provided by a personal computer (PC), a tablet PC, a Set-Top Box (STB), a Personal Digital Assistant (PDA), a cellular telephone, a web appliance, a server, a network router, switch or bridge, or any device capable of executing a set of instructions (sequential or otherwise) that specify actions to be taken by that device. Further, the term “computer” shall include any collection of computers that individually or jointly execute a set (or multiple sets) of instructions to perform any one or more of the methods described herein.

In a further aspect, the computer system 400 may include a processing device 402, a volatile memory 404 (e.g., Random Access Memory (RAM)), a non-volatile memory 406 (e.g., Read-Only Memory (ROM) or Electrically-Erasable Programmable ROM (EEPROM)), and a data storage device 418, which may communicate with each other via a bus 408.

Processing device 402 may be provided by one or more processors such as a general purpose processor (such as, for example, a Complex Instruction Set Computing (CISC) microprocessor, a Reduced Instruction Set Computing (RISC) microprocessor, a Very Long Instruction Word (VLIW) microprocessor, a microprocessor implementing other types of instruction sets, or a microprocessor implementing a combination of types of instruction sets) or a specialized processor (such as, for example, an Application Specific Integrated Circuit (ASIC), a Field Programmable Gate Array (FPGA), a Digital Signal Processor (DSP), or a network processor).

Computer system 400 may further include a network interface device 422 (e.g., coupled to network 474). Computer system 400 also may include a video display unit 410 (e.g., an LCD), an alphanumeric input device 412 (e.g., a keyboard), a cursor control device 414 (e.g., a mouse), and a signal generation device 420.

In some implementations, data storage device 418 may include a non-transitory computer-readable storage medium 424 (e.g., non-transitory machine-readable storage medium) on which may store instructions 426 encoding any one or more of the methods or functions described herein, including instructions encoding components of FIG. 1 and FIG. 2 (e.g., system controller 128, etc.) and for implementing methods described herein.

Instructions 426 may also reside, completely or partially, within volatile memory 404 and/or within processing device 402 during execution thereof by computer system 400, hence, volatile memory 404 and processing device 402 may also constitute machine-readable storage media. While computer-readable storage medium 424 is shown in the illustrative examples as a single medium, the term “computer-readable storage medium” shall include a single medium or multiple media (e.g., a centralized or distributed database, and/or associated caches and servers) that store the one or more sets of executable instructions. The term “computer-readable storage medium” shall also include any tangible medium that is capable of storing or encoding a set of instructions for execution by a computer that cause the computer to perform any one or more of the methods described herein. The term “computer-readable storage medium” shall include, but not be limited to, solid-state memories, optical media, and magnetic media.

The methods, components, and features described herein may be implemented by discrete hardware components or may be integrated in the functionality of other hardware components such as ASICS, FPGAs, DSPs or similar devices. In addition, the methods, components, and features may be implemented by firmware modules or functional circuitry within hardware devices. Further, the methods, components, and features may be implemented in any combination of hardware devices and computer program components, or in computer programs.

Unless specifically stated otherwise, terms such as “determining,” “causing,” “coupling,” “delivering,” “changing,” “receiving,” “performing,” “providing,” “obtaining,” “accessing,” “adding,” “using,” “training,” or the like, refer to actions and processes performed or implemented by computer systems that manipulates and transforms data represented as physical (electronic) quantities within the computer system registers and memories into other data similarly represented as physical quantities within the computer system memories or registers or other such information storage, transmission or display devices. Also, the terms “first,” “second,” “third,” “fourth,” etc. as used herein are meant as labels to distinguish among different elements and may not have an ordinal meaning according to their numerical designation.

Examples described herein also relate to an apparatus for performing the methods described herein. This apparatus may be specially constructed for performing the methods described herein, or it may include a general purpose computer system selectively programmed by a computer program stored in the computer system. Such a computer program may be stored in a computer-readable tangible storage medium.

The methods and illustrative examples described herein are not inherently related to any particular computer or other apparatus. Various general purpose systems may be used in accordance with the teachings described herein, or it may prove convenient to construct more specialized apparatus to perform methods described herein and/or each of their individual functions, routines, subroutines, or operations. Examples of the structure for a variety of these systems are set forth in the description above.

The above description is intended to be illustrative, and not restrictive. Although the present disclosure has been described with references to specific illustrative examples and implementations, it will be recognized that the present disclosure is not limited to the examples and implementations described. The scope of the disclosure should be determined with reference to the following claims, along with the full scope of equivalents to which the claims are entitled.

What is claimed is:

1. A system comprising:
a support base comprising a conductive material, wherein the support base is to support an activation region; and
a microwave annealing chamber, configured to perform a microwave annealing operation on the activation region supported by the support base to activate the activation region, wherein the support base is disposed within a processing volume of the microwave annealing chamber.

2. The system of claim 1, wherein the activation region supported by the support base receives microwaves during the microwave annealing operation.

3. The system of claim 2, wherein a frequency of the microwaves of the microwave annealing operation ranges from 100 kilohertz to 300 gigahertz.

4. The system of claim 2, wherein the microwaves are high-power microwaves ranging from one kilowatt to 50 kilowatts.

5. The system of claim 1, wherein the microwave annealing chamber is further configured to:
deliver electromagnetic radiation to the activation region and the support base, wherein the support base is configured to reflect electromagnetic radiation away from the activation region.

6. The system of claim 1, wherein the support base comprises a doped substrate, and wherein the activation region is disposed on the doped substrate.

7. The system of claim 1, wherein the support base comprises a substrate carrier.

8. The system of claim 1, wherein the support base comprises a substrate support pedestal disposed within the processing volume and operable to support the activation region.

9. A method comprising:
coupling an activation region to a support base, wherein the support base comprises a conductive material; and
causing the activation region coupled to the support base to undergo a microwave annealing operation in a processing chamber to activate the activation region.

10. The method of claim 9, wherein the activation region supported by the support base receives microwaves during the microwave annealing operation.

11. The method of claim 10, wherein a frequency of the microwaves of the microwave annealing operation ranges from 100 kilohertz to 300 gigahertz.

12. The method of claim 10, wherein the microwaves are high-power microwaves ranging from one kilowatt to 50 kilowatts.

13. The method of claim 9, wherein the causing the activation region coupled to the support base to undergo a microwave annealing operation in a processing chamber to activate the activation region comprises:
delivering electromagnetic radiation to the activation region and the support base, wherein the support base is configured to reflect electromagnetic radiation away from the activation region.

14. The method of claim 9, wherein the support base comprises a doped substrate, and wherein the activation region is disposed on the doped substrate.

15. The method of claim 9, wherein the support base comprises a substrate carrier.

16. The method of claim 9, wherein the support base comprises a substrate support pedestal disposed within a processing volume of the processing chamber and operable to support the activation region.

17. A substrate carrier disposed within a processing volume of a microwave annealing chamber, wherein the substrate carrier is to support a substrate comprising a activation region, wherein the substrate carrier comprises a conductive material, and wherein the microwave annealing chamber is configured to perform a microwave annealing operation on the substrate to activate the activation region of the substrate.

18. The substrate carrier of claim 17, wherein the substrate carrier comprises a substrate support pedestal.

19. The substrate carrier of claim 17, wherein during the microwave annealing operation a temperature of the substrate does not exceed 400 degrees Celsius.

20. The substrate carrier of claim 17, wherein the microwave annealing chamber is further configured to:
deliver electromagnetic radiation to the substrate and the substrate carrier, wherein the substrate carrier is configured to reflect electromagnetic radiation away from the substrate.
